(19) United States
(12) Patent Application Publication
(10) Pub. No.: US 2008/0123433 A1
(43) Pub. Date: May 29, 2008

(54) FLASH MEMORY DEVICE AND METHOD OF MANUFACTURING THE SAME

(75) Inventors: Suk-Kang SUNG, Gyeonggi-do (KR); Choong-Ho LEE, Gyeonggi-do (KR); Kyu-Charn PARK, Gyeonggi-do, (KR); Byung-Yong CHOI, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/946,721

(22) Filed: Nov. 28, 2007

(30) Foreign Application Priority Data
Nov. 28, 2006 (KR) 2006-118237

(51) Int. Cl. G11C 11/34

(52) U.S. Cl. 365/185.26

(57) ABSTRACT

A flash memory device is disclosed. The flash memory device includes a substrate, a memory cell transistor and a selection transistor. The substrate has a first region where the memory cell transistor is to be formed and a second region where the selection transistor is to be formed. The first region has an upper surface located within a first plane and the second region has an upper surface located within a second plane different from the first plane. The memory cell transistors may have a Fin-FET structure. The flash memory device may prevent a disturbance phenomenon in which an electron-hole pair infiltrates the memory cell transistor caused by a high integration degree of the flash memory device.

### CROSS-REFERENCE TO RELATED APPLICATION

This application claims the benefit of foreign priority under 35 USC § 119 to Korean Patent Application No. 2006-118237 filed on Nov. 28, 2006, the contents of which are herein incorporated by reference in its entirety for all purposes.

### BACKGROUND

1. Field of Invention

Exemplary embodiments described herein relate generally to flash memory devices and methods of manufacturing the same. More particularly, exemplary embodiments described herein relate to a NAND-type flash memory device and a method of manufacturing the same.

2. Description of the Related Art

Generally, a semiconductor memory device may be classified as a volatile memory device (e.g., a dynamic random access memory (DRAM), a static random access memory (SRAM), etc., which lose data over time), or a non-volatile memory device such as a read only memory (ROM). Non-volatile memory devices can continuously store data, regardless of the passage of time. Further, non-volatile memory devices such as electrically erasable programmable read only memory (EEPROM) devices, which are capable of inputting/outputting data, have been widely developed. Flash memory devices can be considered an advanced type of EEPROM device. Flash memory devices may electrically control the input/output of data using Fowler-Nordheim (F-N) tunneling or channel hot electron injection.

Flash memory devices may be classified as NAND-type flash memory devices or NOR-type flash memory devices, depending on the circuits included therein. NAND-type flash memory devices may include “N” numbers of cell transistors. The “N” numbers of cell transistors may be connected to each other in sequence to form a unit string. A plurality of unit strings may be connected between a bit line and a ground line in parallel. In contrast, NOR-type flash memory devices include cell transistors that are each connected between a bit line and a ground line in parallel. NOR-type flash memory devices are desirable upon considering their rapid operational speed. In contrast, NAND-type flash memory devices are desirable considering their high degree of integration.

FIG. 1 is a circuit diagram illustrating a conventional NAND-type flash memory device.

Referring to FIG. 1, a conventional NAND-type flash memory device has a structure including a plurality of strings, only one of which is illustrated. As illustrated, the string includes a plurality of cell transistors CT0 to CT31, a ground selection transistor GST and a string selection transistor SST.

As memory cells become highly integrated, the distance between the ground and string selection transistors GST and SST and the cell transistors CT0 to CT31 in the NAND-type flash memory device becomes shorter. When a program-preventing voltage is applied to the string selection transistor SST to suppress the NAND-type flash memory device from being programmed, an electron-hole pair may be created due to a gate-induced-drain-leakage (GIDL) phenomenon. The electron-hole pair may be accelerated by an energy field and may thus infiltrate a floating gate of the cell transistor CT31 adjacent to the string selection transistor SST. Such a phenomenon is herein referred to as a “disturbance phenomenon.”

To reduce the disturbance phenomenon, the distance between the cell transistor CT31 and the selection transistor SST can be widened. However, as the distance between the cell transistor CT31 and the selection transistor SST is widened, the degree with which the NAND-type flash memory device can be efficiently integrated into a circuit design is undesirably reduced.

### SUMMARY

Exemplary embodiments described herein may be characterized as providing a NAND-type flash memory device that has a reduced disturbance by controlling heights of regions where a memory cell transistor and a selection transistor are to be formed. Exemplary embodiments described herein may also be characterized as providing a method of manufacturing the above-mentioned NAND-type flash memory device.

One embodiment exemplarily described herein can be generally characterized as a flash memory device that includes a substrate having a first region and a second region, the first region having an upper surface located within a first plane and the second region having an upper surface located within a second plane different from the first plane. A memory cell transistor may be formed on the first region. The memory cell transistor may include a Fin-FET structure. A selection transistor may be formed on the second region.

Another embodiment exemplarily described herein can be generally characterized as a flash memory device that includes a substrate having a first region, a second region and a recess formed at an interface between the first region and the second region. A memory cell transistor may be formed on the first region and a selection transistor may be formed on the second region. The memory cell transistor and the selection transistor may include a Fin-FET structure.

Yet another embodiment exemplarily described herein can be generally characterized as a method of manufacturing a flash memory device that includes preparing a substrate having a first region and a second region. The first region may have an upper surface located within a first plane and the second region having an upper surface located within a second plane different from the first plane. A memory cell transistor may be formed on the first region and may include a Fin-FET structure. A selection transistor may be formed on the second region.

Still another embodiment exemplarily described herein can be generally characterized as a method of manufacturing a flash memory device that includes preparing a substrate having a first region, a second region and a recess formed at an interface between the first region and the second region. A memory cell transistor may be formed on the first region and include a Fin-FET structure. A selection transistor may be formed on the second region and include a Fin-FET structure.

### BRIEF DESCRIPTION OF THE DRAWINGS

The above and other embodiments will become readily apparent by reference to the following detailed description when considered in conjunction with the accompanying drawings wherein:

FIG. 1 is a block diagram illustrating a conventional NAND-type flash memory device;

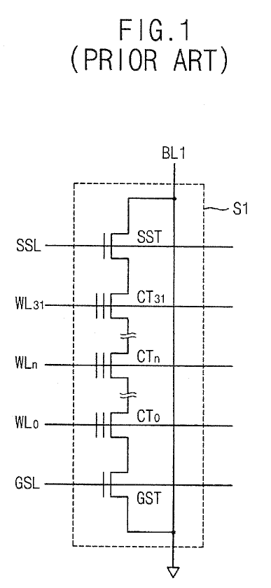

FIG. 2 is a plan view illustrating a layout of a NAND-type flash memory device in accordance with a first exemplary embodiment;

FIG. 3 is a cross-sectional view taken along line Y-Y′ shown in FIG. 2;

FIG. 4 is a cross-sectional view taken along line X-X′ shown in FIG. 2;

FIG. 5 is a cross-sectional view illustrating a NAND-type flash memory device in accordance with a second exemplary embodiment;

FIG. 6 is a cross-sectional view illustrating a NAND-type flash memory device in accordance with a third exemplary embodiment;

FIGS. 7 to 11 are cross-sectional views illustrating an exemplary method of manufacturing the flash memory device shown in FIG. 3;

FIGS. 12 and 13 are cross-sectional views illustrating an exemplary method of manufacturing the flash memory device shown in FIG. 5; and

FIGS. 14 and 15 are cross-sectional views illustrating an exemplary method of manufacturing the flash memory device shown in FIG. 6.

### DETAILED DESCRIPTION

Exemplary embodiments of the present invention will now be described more fully hereinafter with reference to the accompanying drawings. These embodiments may, however, be realized in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the embodiments described herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

NAND-Type Flash Memory Device

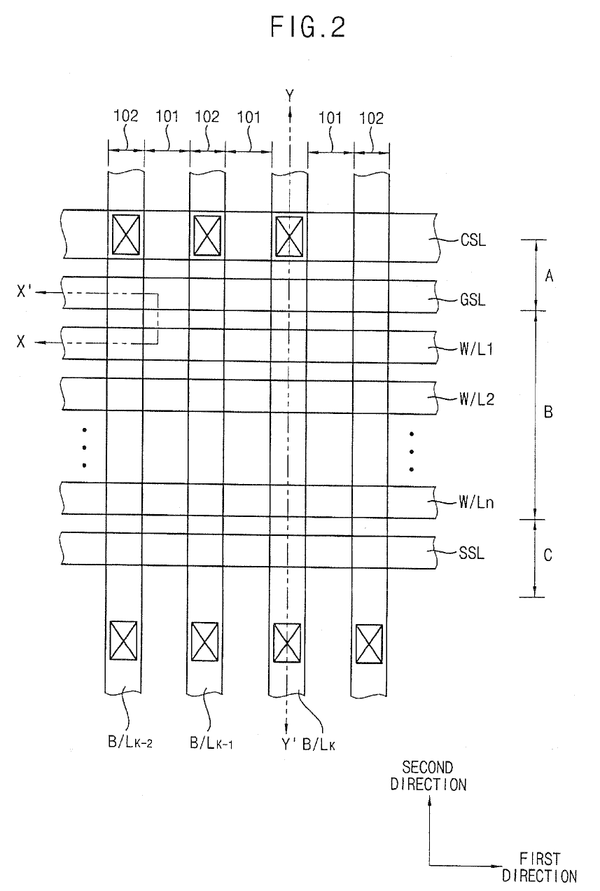

FIG. 2 is a plan view illustrating a layout of a NAND-type flash memory device in accordance with a first exemplary embodiment.

Referring to FIG. 2, field regions 101 are formed between active regions 102. Thus, the active regions 102 are spaced apart from each other along a first direction. Further, the active regions 102 are extend along a second direction substantially perpendicular to the first direction such that the active regions 102. Accordingly, the active regions 102 are substantially parallel with each other. A channel region (not shown) and impurity regions (not shown) of a memory cell transistor are formed in an active region 102.

Memory cell transistors are formed on the active region 102. In one embodiment, the memory cell transistors have a stacked gate structure including a floating gate (not shown) and a control gate corresponding to a word line. “N” word lines W/L₁, W/L₂, . . . , W/Lₙ (also referred to herein as “conductive lines”) extend substantially along the first direction. Further, the word lines W/L₁, W/L₂, . . . , and W/Lₙ are repeatedly arranged substantially along the second direction Heavily doped impurity regions (not shown) may be formed in portions of the active region 102 between adjacent the word lines W/L₁, W/L₂, . . . , W/Lₙ so as to be spaced apart from each other.

When a plurality of memory cell transistors are arranged along the second direction (e.g., by arranging active regions 102, which extend along the second direction, and word lines W/L₁, W/L₂, . . . , W/Lₙ, which extend along the first direction), a ground selection line GSL and a string selection line SSL, each associated with a selection transistor, may be formed outside the first word line W/L₁ and the n^{th} word line W/Lₙ to form a string as a single memory unit. A plurality of strings may be arranged along the first direction to form a memory cell array. The ground selection line GSL is associated with a ground selection transistor GST and the string selection line SSL is associated with a string selection transistor SST. Within the string, “n” numbers of memory cell transistors are connected to each other in series and commonly share impurity regions. For example, a conductive line may include a selection line.

The ground selection transistor and the string selection transistor may include a butting contact (not shown). The butting contact is formed on the field region 101 between an input and an output to connect a floating gate and a control gate to each other. The butting contact may prevent a signal delay due to a resistance. Thus, the selection transistors may be electrically operated as a MOS transistor having a single-layered gate.

“K” numbers of bit lines B/Lₖ, B/Lₖ₋₁, . . . , B/Lₖ₋₂ are formed on the word lines W/L₁, W/L₂, . . . , W/Lₙ. The bit lines B/Lₖ, B/Lₖ₋₁, . . . , B/Lₖ₋₂ extend substantially along the second direction. Thus, the bit lines B/Lₖ, B/Lₖ₋₁, . . . , B/Lₖ₋₂ are substantially perpendicular to the word lines W/L₁, W/L₂, . . . , W/Lₙ. Further, the bit lines B/Lₖ, B/Lₖ₋₁, . . . , B/Lₖ₋₂ are repeatedly arranged along the first direction. Bit line contacts are formed at one side of the strings adjacent to the string selection line SSL and common source contacts are formed at the other side of the string adjacent to the ground selection line GSL. The common source contact is coupled to a common source line CSL that extends substantially along the first direction adjacent to the ground selection line GSL.

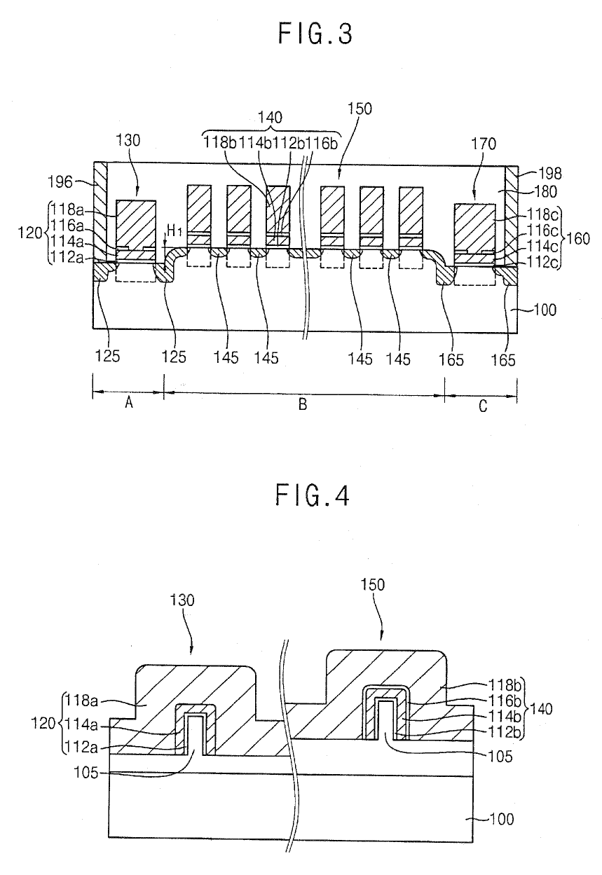

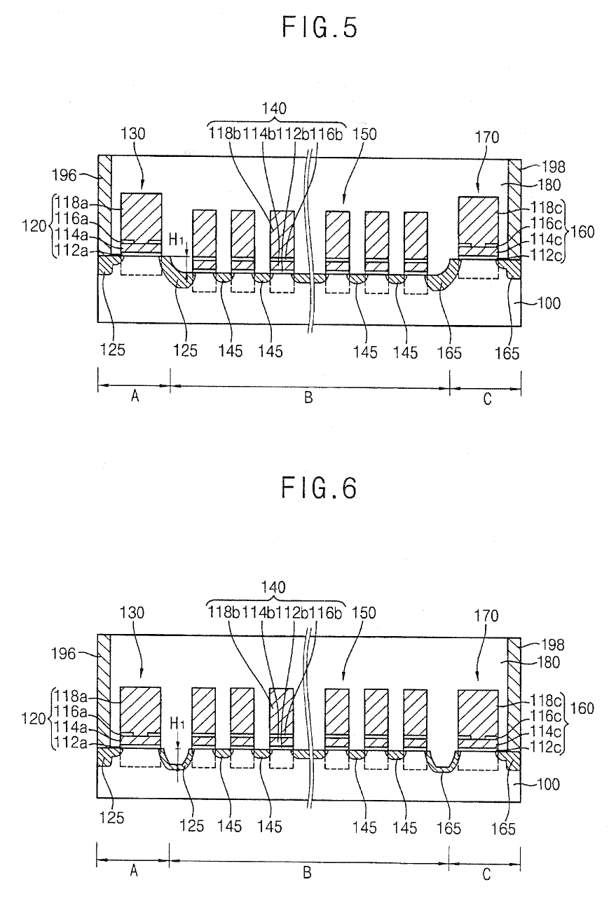

FIG. 3 is a cross-sectional view taken along line Y-Y′ shown in FIG. 2. FIG. 4 is a cross-sectional view taken along line X-X′ shown in FIG. 2.

Referring to FIGS. 3 and 4, the NAND-type flash memory device may, for example, include a substrate 100 having a first region B where memory cell transistors are to be formed and second ground region A and the second string region C (herein collectively referred to as “second regions A and C”) where selection transistors are to be formed. A plurality of memory cell transistors 150 are formed on the first region B of the substrate 100, a ground selection transistor 130 is formed in second ground region A and a string selection transistor 170 is formed in second selection region C.

An upper surface of the first region B of the substrate 100 is higher than or lower than upper surfaces of the second regions A and C. In the illustrated embodiment, the upper surface of the first region B may be higher than the upper surface of the second region. Further, the substrate 100 is divided into an active region (not shown) and a field region (not shown) by an isolation layer (not shown).

As mentioned above, the second region includes a second string region C where the string selection transistor 170 is to be formed and a second ground region A where the ground selection transistor 130 is to be formed. In the illustrated embodiment, the second ground region A may be located at one side of the first region B and the second string region C may be located at the other side of the first region B.

The ground selection transistor 130 may include a first gate structure 120 formed on the second selection region A of the substrate 100 and first impurity regions 125 formed in the substrate 100 adjacent to the first gate structure 120.

In the illustrated embodiment, the first gate structure 120 may have a fin field effect transistor (Fin-FET) structure including a silicon fin 105 having an upper surface higher than an upper surface of an isolation layer pattern adjacent thereto. In another embodiment, however, the first gate structure 120 may have a substantially planar structure. In such an embodiment, the first gate structure 120 having the substantially planar structure may be formed on a portion of the substrate 100 having an upper surface that is substantially coplanar with the upper surface of the isolation layer pattern.

In one embodiment, the first gate structure 120 includes an insulation layer pattern 112a, a first conductive layer pattern 114a, a dielectric layer pattern 116a and a second conductive layer pattern 118a. The first conductive layer pattern 114a and the second conductive layer pattern 118a may be electrically connected to each other through a trench formed in the dielectric layer pattern 116a. In another embodiment, the first gate structure 120 includes an insulation layer pattern and a gate electrode formed on the insulation layer pattern. The first impurity regions 125 of the ground selection transistor 120 may be electrically coupled to a source contact 196.

The memory cell transistor 150 may include a second gate structure 140 formed in the first region B of the substrate 100 and second impurity regions 145 adjacent to the second gate structure 140. The second gate structure 140 may have a Fin-FET structure.

In the illustrated embodiment, the second gate structure 140 may have a structure including a silicon fin 105 having an upper surface higher than an upper surface of the isolation layer pattern. In one embodiment, the upper surfaces of the silicon fins 105 on the first region B and the second region A and C may be substantially coplanar. In another embodiment, the upper surfaces of the silicon fins 105 on the first region B and the second region A and C may not be substantially coplanar. For example, the upper surface of the silicon fin 105 on the first region B may be higher than upper surfaces of silicon fin 105 on the second regions A and C. In such an embodiment, the upper surface of the memory cell transistor 150 may be higher than upper surfaces of the ground and string selection transistors 130 and 170.

In one embodiment, the second gate structure 140 includes a tunnel insulation layer pattern 112b, a floating gate 114b, a dielectric layer pattern 116b and a control gate 118b. In another embodiment, the second gate structure 140 includes a tunnel insulation layer pattern, a charge-trapping pattern, a blocking pattern and an electrode. The second impurity regions 145 may be formed in the upper face of the silicon fin 105.

The string selection transistor 170 may include a third gate structure 160 formed on the second string region C of the substrate 100 and third impurity regions 165 formed in the substrate 100 adjacent to the third gate structure 160.

In one embodiment, although not illustrated, the third gate structure 160 may have a Fin-FET structure including a silicon fin (not shown) having an upper surface higher than an upper surface of an isolation layer pattern adjacent thereto. In another embodiment, however, the third gate structure 160 may have a substantially planar structure. In such an embodiment, the third gate structure 160 having the substantially planar structure may be formed on a portion of the substrate 100 having an upper surface that is substantially coplanar with the upper surface of the isolation layer pattern.

In one embodiment, the third gate structure 160 includes an insulation layer pattern and a gate electrode formed on the insulation layer pattern. In such an embodiment, the third gate structure 160 may include an insulation layer pattern 112c, a first conductive layer pattern 114c, a dielectric layer pattern 116c and a second conductive layer pattern 118c. The first conductive layer pattern 114c and the second conductive layer pattern 118c may be electrically connected to each other through a trench formed in the dielectric layer pattern 116c. Further, the third impurity regions 165 of the string selection transistor 170 may be electrically coupled to a bit line contact 198.

In the NAND-type flash memory device having the above-described structure, the memory cell transistor 150 may be located on a portion of the substrate 100 that is higher than other portions of the substrate 100 on which the ground selection transistor 130 and the string selection transistor 170 are located. Thus, the second impurity regions 145 of the memory cell transistor 150 may be positioned above the first impurity regions 125 of the ground selection transistor 1330 and the third impurity regions 165 of the string selection transistor 170. As a result, the disturbance phenomenon, where an electron-hole pair infiltrates the memory cell transistor 150 due to a high integration degree of the flash memory device, may not be increased. Further, an effective distance between the selection transistor and the memory cell transistor may be sufficiently ensured. Furthermore, the memory cell transistor having the Fin-FET structure may prevent a gate induced drain leakage (GIDL) from being increased.

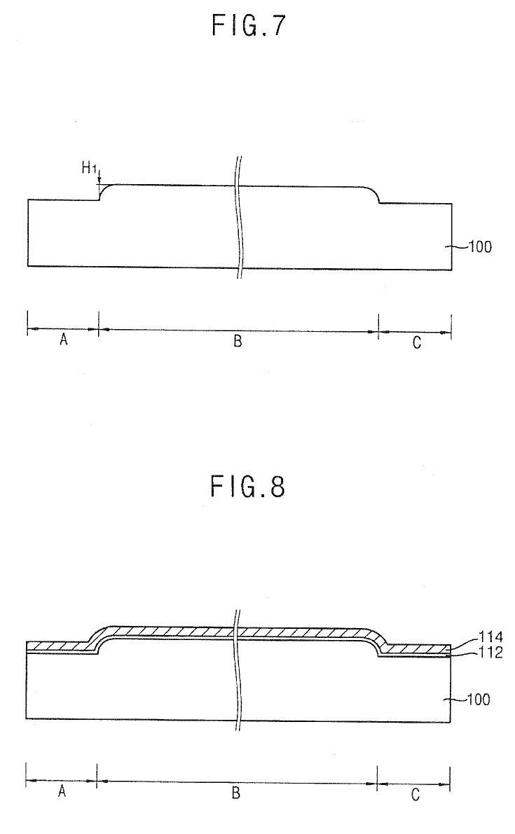

FIG. 5 is a cross-sectional view illustrating a NAND-type flash memory device in accordance with a second exemplary embodiment.

Referring to FIG. 5, a NAND-type flash memory device may, for example, include a substrate 100 having a first region B where a memory cell transistor 150 is to be formed, a second ground region A where a ground selection transistor 130 is to be formed and a second string region C where a string selection transistor 170 is to be formed. In the illustrated embodiment, the first region B may have an upper surface that is lower than upper faces of the second ground region A and the second string region C. Further, the NAND-type flash memory device may further include the ground selection transistor 130, the memory cell transistor 150 and the string selection transistor 170.

The ground selection transistor 130 may, for example, include a first gate structure 120 formed on the second selection region A of the substrate 100 and first impurity regions 125 formed in the substrate 100 adjacent to the first gate structure 120.

In one embodiment, although not illustrated, the first gate structure 120 may have a Fin-FET structure including a silicon fin having an upper surface higher than an upper surface of an isolation layer pattern adjacent thereto. In another embodiment, the first gate structure 120 may have a substantially planar structure. Further, first impurity regions 125 of the ground selection transistor 120 may be electrically coupled to a source contact 196.

The memory cell transistor 150 may, for example, include a second gate structure 140 formed in the first region B of the substrate 100 and second impurity regions 145 adjacent to the second gate structure 140. The second gate structure 140 may have a Fin-FET structure.

The string selection transistor 170 may, for example, include a third gate structure 160 formed on the second string region C of the substrate 100 and third impurity regions 165 formed in the substrate 100 adjacent to the third gate structure 160. In one embodiment, the third gate structure 160 may have a Fin-FET structure including a silicon fin (not shown) having an upper surface higher than an upper surface of an isolation layer pattern adjacent thereto. In another embodiment, the third gate structure 160 may have a substantially planar structure. Further, third impurity regions 165 of the string selection transistor 170 may be electrically coupled to a bit line contact 198.

In one embodiment, the upper surfaces of the silicon fins on the first region B and the second region A and C may be substantially coplanar. In another embodiment, the upper surfaces of the silicon fins on the first region B and the second region A and C may not be substantially coplanar. For example, the upper surfaces of the silicon fins on the second regions A and C may be higher than the upper surface of the silicon fin on the first region B. In such an embodiment, the upper surfaces of the ground and string selection transistors 130 and 170 may be higher than the upper surface of the memory cell transistor 150.

The ground selection transistor 130, the memory cell transistor 150 and the string selection transistor 170 are substantially similar to those in FIG. 3, respectively. Thus, any further description with respect to the ground selection transistor 130, the memory cell transistor 150 and the string selection transistor 170 are omitted herein for brevity.

In the NAND-type flash memory device having the above-described structure, the ground selection transistor 130 and the string selection transistor 170 may be located on portions of the substrate 100 that are higher than a portion of the substrate 100 on which the memory cell transistor 150 is formed. Thus, the second impurity regions 145 of the memory cell transistor 150 may be positioned lower than the first impurity regions 125 of the ground selection transistor 130 and the third impurity regions 165 of the string selection transistor 170. As a result, the disturbance phenomenon, where an electron-hole pair infiltrates the memory cell transistor 150 due to a high integration degree of the flash memory device, may not be increased. Further, an effective distance between the selection transistor and the memory cell transistor may be sufficiently ensured. Furthermore, the memory cell transistor having the Fin-FET structure may prevent a gate induced drain leakage (GIDL) from being increased.

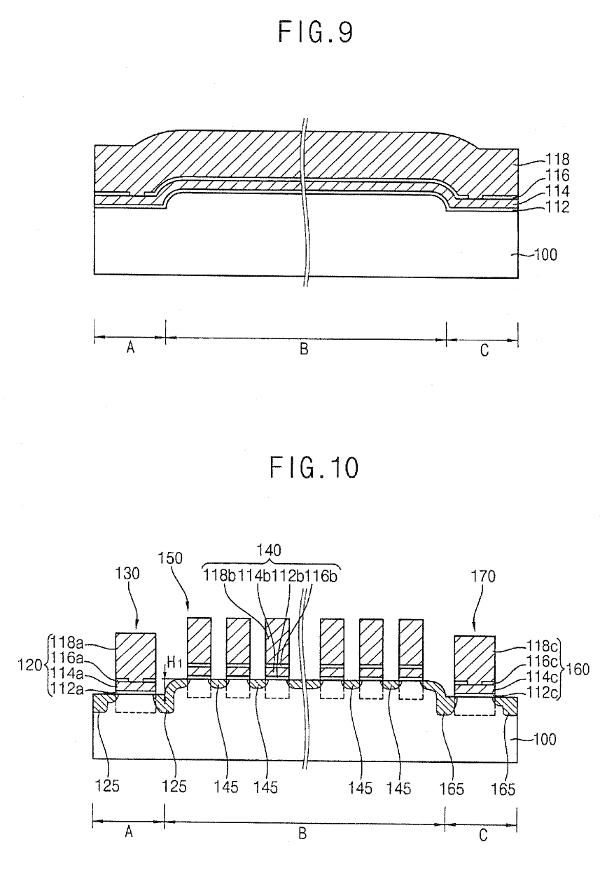

FIG. 6 is a cross-sectional view illustrating a NAND-type flash memory device in accordance with a third example embodiment of the present invention.

Referring to FIG. 6, a NAND-type flash memory device may, for example, include a substrate 100 having recesses R, a ground selection transistor 130, a memory cell transistor 150 and a string selection transistor 170. The substrate 100 has a first region B where the memory cell transistor 150 is to be formed, a second ground region A where the ground selection transistor 130 is to be formed, and a second string region C where the string selection transistor 170 is to be formed. The recesses R are formed at a first interface between the first region B and the second ground region A and at a second interface between the first region B and the second string region C.

The ground selection transistor 130 may, for example, include a first gate structure 120 formed on the second selection region A of the substrate 100 and first impurity regions 125 formed in the substrate 100 adjacent to the first gate structure 120.

In one embodiment, although not illustrated, the first gate structure 120 may have a Fin-FET structure including a silicon fin having an upper face higher than an upper surface of an isolation layer pattern adjacent thereto. In another embodiment, the first gate structure 120 may have a substantially planar structure. Further, first impurity regions 125 of the ground selection transistor 120 may be electrically coupled to a source contact 196.

The memory cell transistor 150 may, for example, include a second gate structure 140 formed in the first region B of the substrate 100 and second impurity regions 145 adjacent to the second gate structure 140. The second gate structure 140 may have a Fin-FET structure.

The string selection transistor 170 may, for example, include a third gate structure 160 formed on the second string region C of the substrate 100 and third impurity regions 165 formed in the substrate 100 adjacent to the third gate structure 160. Further, third impurity regions 165 of the string selection transistor 170 may be electrically coupled to a bit line contact 198.

The ground selection transistor 130, the memory cell transistor 150 and the string selection transistor 170 are substantially the same as those in FIG. 3, respectively. Thus, any further description with respect to the ground selection transistor 130, the memory cell transistor 150 and the string selection transistor 170 are omitted herein for brevity.

In the NAND-type flash memory device having the above-described structure, the recess R may be formed at the interface of the substrate between the first region B and the second regions A and C. Thus, an effective distance between the selection transistor and the memory cell transistor may be sufficiently ensured. Further, the memory cell transistor having the Fin-FET structure may prevent a gate induced drain leakage (GIDL) from being increased.

Method of Manufacturing a Flash Memory Device

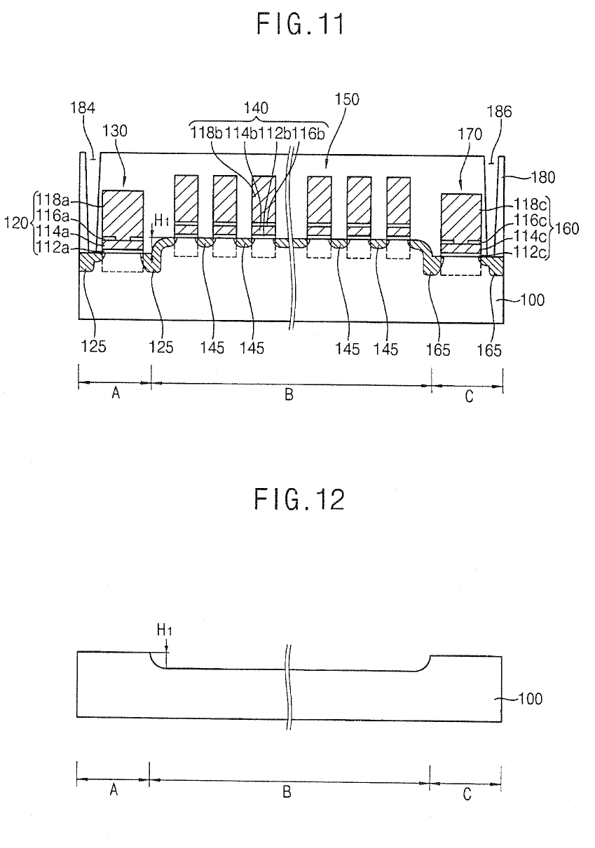

FIGS. 7 to 11 are cross-sectional views illustrating an exemplary method of manufacturing the flash memory device in FIG. 3. In FIGS. 7 to 11, the same reference numerals refer to the same elements in FIG. 3.

Referring to FIG. 7, a substrate 100 is prepared. The substrate 100 has a first region B, a second ground region A and a second selection region C. Further, an upper surface of the first region B is higher than upper surfaces of the second ground region A and the second selection region C. Accordingly, the substrate 100 has a step height H₁. Furthermore, the substrate 100 has an active region and a field region defined by an isolation layer (not shown). The active region of the substrate 100 may correspond to a silicon pattern.

In one embodiment, the substrate 100 may be prepared by forming a hard mask (not shown) on a silicon substrate having the isolation layer. The hard mask may be formed on the first region B. The second regions A and C of the silicon substrate may then be etched using the hard mask as an etching mask to form the substrate 100 having the first region B, the second ground region A and the second selection region C. As mentioned above, the upper surface of the first region B may be higher than upper surfaces of the second ground region A and the second selection region C. In one embodiment, upper surfaces of isolation layers on the second regions A and C (not shown) may be substantially coplanar with upper surfaces of the etched portions of the silicon substrate in the second regions A and C. In another embodiment, upper surfaces of the isolation layers on the second regions A and C may be higher than upper surfaces of the etched portions of the silicon substrate in the second regions A and C. The hard mask may be removed by a cleaning process using a cleaning solution including phosphorous.

In another embodiment, the substrate 100 may be prepared by forming a hard mask (not shown) on a silicon substrate having the isolation layer. The hard mask may be formed on the second regions A and C. A silicon epitaxial growth process may then be carried out on the first region A of the silicon substrate exposed by the hard mask to form the substrate 100 having the first region B, the second ground region A and the second selection region C. As mentioned above, the upper surface of the first region B may be higher than upper surfaces of the second ground region A and the second selection region C. The hard mask may be removed by a cleaning process using a cleaning solution including phosphorous.

An upper portion of the isolation layer on the substrate 100 having the step height H₁ is then removed to expose the side face of the silicon pattern corresponding to the active region of the substrate 100. Accordingly, a silicon fin structure corresponding to the silicon pattern having an exposed side face is defined.

In the embodiment shown in FIG. 4, the silicon fin structure may be formed on the first region B and the second regions A and C of the substrate 100. Although not illustrated, the silicon fin structure may, in one embodiment, be formed only on the first region B. Further, upper surfaces of the active regions in the second regions A and C may be substantially coplanar with upper surfaces of the isolation layer.

Referring to FIG. 8, a first insulation layer 112 is formed on the substrate 100 having the silicon fin structure. In one embodiment, the first insulation layer 112 may be formed using a thermal oxidation process. For example, the first insulation layer 112 may be formed on a portion of the silicon substrate 100 exposed through the isolation layer or a surface of the silicon fin structure.

A first portion of the first insulation layer 112 on the first region B may be used as a tunnel oxide layer of a cell memory transistor. A second portion of the first insulation layer 112 on the second ground region A may be used as a gate oxide layer of a ground selection transistor. A third portion of the first insulation layer 112 on the second string region C may be used as a gate oxide layer of a string selection transistor. Thus, the gate oxide layers and the tunnel oxide layer may be simultaneously formed on the substrate 100 by performing a single thermal oxidation process.

A preliminary conductive layer (not shown) having a substantially uniform thickness is then formed on the substrate 100 having the first insulation layer 112. In one embodiment, the preliminary conductive layer may include polysilicon doped with impurities, a metal, or the like, or a combination thereof, formed using a chemical vapor deposition (CVD) process, or the like. In another embodiment, a silicon nitride layer serving as a charge-trapping layer may be formed on the substrate 100 in place of the preliminary conductive layer. The preliminary conductive layer is patterned along a direction substantially parallel with a direction along which the isolation layer extends. That is, the preliminary conductive layer is patterned along a direction substantially perpendicular to a direction along which a word line extends to form a first conductive layer 114 only on the active region. The first conductive layer 114 may surround (or substantially surround) the silicon fin structure having the first insulation layer 112.

A first portion of the first conductive layer 114 on the first region B may be used as a floating gate of the cell memory transistor. A second portion of the first conductive layer 114 on the second ground region A may be used as an electrode of the ground selection transistor A third portion of the first conductive layer 114 on the second string region C may be used as an electrode of the string selection transistor.

Referring to FIG. 9, a dielectric layer 116 having a substantially uniform thickness is formed on the first conductive layer 114. In one embodiment, the dielectric layer 116 may have an oxide/nitride/oxide (ONO) structure. In another embodiment, the dielectric layer 116 may include a material having a high dielectric constant for providing the dielectric layer 116 with a thin equivalent oxide thickness (EOT) and for reducing a leakage current through the dielectric layer 116. The dielectric layer 116 may, for example, include hafnium oxide, zirconium oxide, tantalum oxide, aluminum oxide, titanium oxide, rubidium oxide, magnesium oxide, strontium oxide, boron oxide, lead oxide, calcium oxide, or the like or a combination thereof.

In one embodiment, the dielectric layer 116 may have a multi-layered structure where a silicon oxide layer, a silicon nitride layer and a layer having a high dielectric constant are sequentially stacked. For example, when the first conductive layer 114 includes the silicon nitride layer as the charge-trapping layer, the dielectric layer 116 may be used as a blocking layer.

Trenches (not shown) are then formed in the second ground region A and the second string region C to expose the surface of the first conductive layer 114. In one embodiment, the trenches may serve as a butting contact hole for allowing a subsequently-formed second conductive layer to be used as a gate electrode electrically connected to the first conductive layer 114.

The second conductive layer 118 is then formed on the dielectric layer 116. The second conductive layer 118 may include a conductive material suitable for forming a gate electrode or a control gate. In one embodiment, the conductive material may, for example, include polysilicon or a metal having a work function of not less than about 4.0 eV. The second conductive layer 118 may have a single-layered structure including, for example, a single polysilicon layer doped with impurities or a multi-layered structure including, for example, a polysilicon layer doped with impurities and a metal layer, sequentially stacked.

A mask pattern (not shown) is then formed on the second conductive layer 118. In one embodiment, the mask pattern may include a material such as silicon nitride. The mask pattern may define regions where a first gate structure 120 of the ground selection transistor, a second gate structure 140 of the cell memory transistor and a third gate structure 160 of the string selection transistor are to be formed, respectively.

Referring to FIG. 10, the second conductive layer 118, the dielectric layer 116, the first conductive layer 114 and the first insulation layer 112 are etched using the mask pattern as an etching mask to form the first gate structure 120, the second gate structure 140 and the third gate structure 160. The first gate structure 120 may correspond to a ground selection line of the ground selection transistor. The second gate structure 140 may correspond to a word line of the memory cell transistor. Further, the third gate structure 160 may correspond to a string selection line of the string selection transistor.

In one embodiment, the first gate structure 120 may include an insulation layer pattern 112a, a first conductive layer pattern 114a, a dielectric layer pattern 116a and a second conductive layer pattern 118a. The first conductive layer pattern 114a and the second conductive layer pattern 118a in the first gate structure 120 may be electrically connected to each other through the trench in the dielectric layer pattern 116a.

The second gate structure 140 may include a tunnel oxide layer pattern 112b, a floating gate 114b, a dielectric layer pattern 116b and a control gate 118b.

The third gate structure 160 may include an insulation layer pattern 112c, a first conductive layer pattern 114c, a dielectric layer pattern 116c and a second conductive layer pattern 118c. The first conductive layer pattern 114c and the second conductive layer pattern 118c in the third gate structure 160 may be electrically connected to each other through the trench in the dielectric layer pattern 116c.

Impurities may then be implanted into the substrate 100 to form impurity regions. The impurity regions may include first impurity regions 125, second impurity regions 145 and third impurity regions 165. The first impurity regions 125 may be formed in a portion of the substrate 100 adjacent to the first gate structure 120. For example, the first impurity regions 125 may correspond to a common source region. The second impurity regions 145 may be formed in a portion of the substrate 100 between adjacent second gate structures 140. Further, the second impurity regions 145 may connect memory cells to each other in series. The third impurity regions 165 may be formed in a portion of the substrate 100 adjacent to the third gate structure 160. For example, the third impurity regions 165 may include a drain region. As a result, the ground selection transistor 130, the memory cell transistor 150 and the string selection transistor 170 having fin structures, are respectively formed on the substrate 100 by the above-mentioned processes.

Referring to FIG. 11, an insulation layer 180 is then formed on the substrate 100 to cover the first gate structure 120, the second gate structure 140 and the third gate structure 160. In one embodiment, the insulation layer 180 may, for example, include silicon oxide such as BPSG, PSG, USG, SOG, PE-TEOS, HDP-CVD oxide, or the like or a combination thereof. In one embodiment, materials such as HDP-CVD oxide and SOG can substantially fill spaces between the first to the third gate structures 120, 140 and 160.

The insulation layer may be partially etched using a photolithography process to form a first contact hole 184 exposing the first impurity regions 125 of the ground selection transistor 130 and a second contact hole 186 exposing the third impurity regions 165 of the string selection transistor 170 adjacent to the ground selection transistor 130.

A third conductive layer (not shown) may then be formed on the insulation layer 180 to substantially fill the first contact hole 184 and the second contact hole 186. In one embodiment, the third conductive layer may include a material such as doped polysilicon or the like. The third conductive layer is then partially removed using, for example, a chemical mechanical polishing (CMP) process until the surface of the insulation layer 180 is exposed to form a common source line contact 196 in the first contact hole 184 and a bit line contact 198 in the second contact hole 186 in FIG. 3.

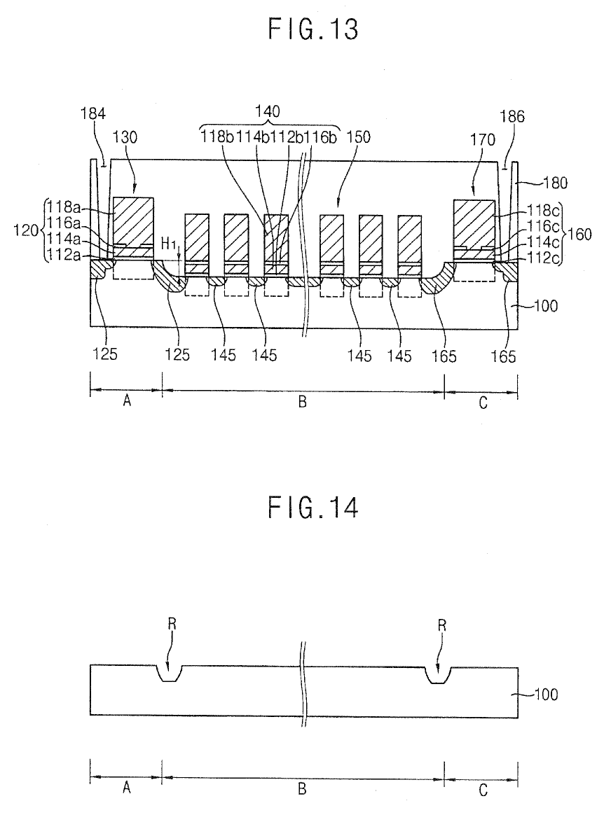

FIGS. 12 and 13 are cross-sectional views illustrating an exemplary method of manufacturing the flash memory device shown in FIG. 5. In FIGS. 12 and 13, the same reference numerals refer to the same elements shown in FIG. 5.

Referring to FIG. 12, a substrate 100 is prepared. The substrate 100 has a first region B, a second ground region A and a second selection region C. Further, an upper surface of the first region B is lower than upper surfaces of the second ground region A and the second selection region C.

In one embodiment, the substrate 100 may be prepared by forming a hard mask (not shown) on a silicon substrate having an isolation layer. The hard mask may be formed on the second regions A and C. The first region B of the silicon substrate may then be etched using the hard mask as an etching mask to form the substrate 100 having the first region B, the second ground region A and the second selection region C. In one embodiment, the upper surface of the isolation layer on the first region B may be substantially coplanar with the upper surface of the etched silicon substrate in the first region B. In another embodiment, the upper surface of the isolation layer on the first region B may be higher than the upper surface of the etched portion of the silicon substrate in the first region B. The hard mask may be removed by a cleaning process using a cleaning solution including phosphorous.

In another embodiment, the substrate 100 may be prepared by forming a hard mask (not shown) on a silicon substrate having the isolation layer. The hard mask may be formed on the first region B. A silicon epitaxial growth process may then be carried out on the second regions A and C of the silicon substrate exposed through the hard mask to form the substrate 100 having the first region B, the second ground region A and the second selection region C. As mentioned above, the upper surfaces of the second regions A and C may be higher than the upper surface of the first region B. The hard mask may be removed by a cleaning process using a cleaning solution including phosphorous.

Referring to FIG. 13, a ground selection transistor 130, a plurality of memory cell transistors 150 and a string selection transistor 170 are formed on the substrate 100. A ground selection transistor 130, a plurality of memory cell transistors 150 and a string selection transistor 170 may be formed in a manner that is substantially the same as that illustrated with reference to FIGS. 8 to 10. Accordingly, any further description with respect to the processes for forming the transistors 130, 150 and 170 are omitted herein for brevity. A process substantially the same as that illustrated with reference to FIG. 11 is then carried out to complete the NAND-type flash memory device shown in FIG. 5.

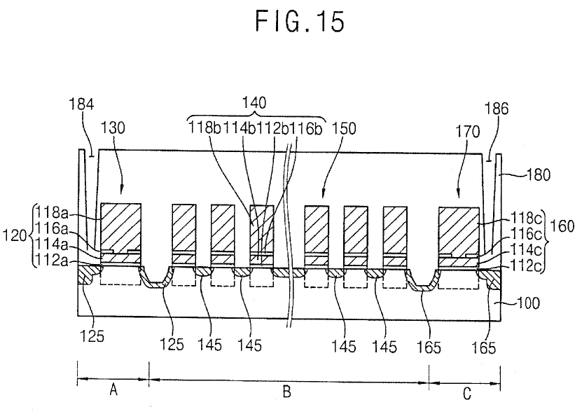

FIGS. 14 and 15 are cross-sectional views illustrating a method of manufacturing the flash memory device shown in FIG. 6. In FIGS. 14 and 15, the same reference numerals refer to the same elements shown in FIG. 6.

Referring to FIG. 14, a substrate 100 is prepared. The substrate 100 has a first region B, a second ground region A and a second selection region C. Further, the substrate 100 has a recess R formed at the interfaces between the first region B and the second regions A and C.

In one embodiment, the substrate 100 may be prepared by forming a hard mask (not shown) on a silicon substrate having an isolation layer. The hard mask may be formed on the first region B and on the second regions A and C but expose portions of the silicon substrate between the first region B and the second regions A and C. The exposed portions of the silicon substrate may then be etched using the hard mask as an etching mask to form the substrate 100 having the recesses R at interfaces between the first region B and the second regions A and C. The hard mask may be removed by a cleaning process using a cleaning solution including phosphorous.

In another embodiment, the substrate 100 may be prepared by forming a hard mask (not shown) on a silicon substrate having the isolation layer. The hard mask may be formed on portions of the silicon substrate between the first region B and the second regions A and C to expose the first region B and the second regions A and C. A silicon epitaxial growth process may then be carried out on the portions of the silicon substrate exposed through the hard mask to form the substrate 100 having the recesses R. The hard mask may be removed by a cleaning process using a cleaning solution including phosphorous.

Referring to FIG. 15, a ground selection transistor 130, a plurality of memory cell transistors 150 and a string selection transistor 170 are formed on the substrate 100. A ground selection transistor 130, a plurality of memory cell transistors 150 and a string selection transistor 170 may be formed in a manner that is substantially the same as that illustrated with reference to FIGS. 8 to 10. Thus, any further illustrations with respect to the processes for forming the transistors 130, 150 and 170 are omitted herein for brevity. A process substantially the same as that illustrated with reference to FIG. 11 is then carried out to complete the NAND-type flash memory device shown in FIG. 6.

According to some embodiments exemplarily described above, a memory cell transistor having a Fin-FET structure may be formed in the first region having the upper surface that is positioned higher or lower than upper surfaces of the second regions so that an effective length between the selection transistor and the memory cell transistor may be sufficiently ensured. According to other embodiments exemplarily described above, a memory cell transistor having a Fin-FET structure may be formed on the substrate having recesses between the first region and the second regions so that the effective length between the selection transistor and the memory cell transistor may be more sufficiently ensured. Thus, a disturbance phenomenon, where an electron-hole pair infiltrates the memory cell transistor due to a high integration degree of the flash memory device, may be prevented. Further, the memory cell transistor having the Fin-FET structure may prevent a gate induced drain leakage (GIDL) from being increased.

Non-limiting examples of embodiments of the present invention will now be described in the paragraphs below.

A flash memory device may include a substrate, a plurality of memory cell transistors and a selection transistor. The substrate has a first region where the memory cell transistors are to be formed, and a second region where the selection transistor is to be formed. Here, the first region has an upper face on a horizontal plane different from that on which an upper face of the second region is positioned. The memory cell transistors are formed in the first region. Further, the memory cell transistors have a Fin-FET structure. The selection transistor is formed in the second region.

According to one embodiment, the upper face of the memory cell transistor may be higher or lower than that of the selection transistor.

In accordance with another embodiment, a flash memory device may include a substrate, a plurality of memory cell transistors and a selection transistor. The substrate has a first region where the memory cell transistors are to be formed, and a second region where the selection transistor is to be formed. Further, the substrate has a recess formed at an interface between the first region and the second region. The memory cell transistors are formed in the first region. Further, the memory cell transistors have a Fin-FET structure. The selection transistor is formed in the second region. Further, the selection transistor has a Fin-FET structure.

In a method of manufacturing a flash memory device, a substrate having a first region where memory cell transistors are to be formed and a second region where a selection transistor is to be formed is prepared. Here, the first region has an upper face on a horizontal plane different from that on which an upper face of the second region is positioned. The memory cell transistors having a Fin-FET structure are formed in the first region. The selection transistor is then formed in the second region to complete the flash memory device.

In another method of manufacturing a flash memory device, a substrate having a first region where memory cell transistors are to be formed and a second region where a selection transistor is to be formed is prepared. Here, the substrate has a recess formed at an interface between the first region and the second region. The memory cell transistors having a Fin-FET structure are formed in the first region. The selection transistor having a Fin-FET structure is then formed in the second region to complete the flash memory device.

According to the embodiments exemplarily described above, the memory cell transistor having the Fin-FET structure may be formed in the first region having the upper face that is positioned on the horizontal plane different from that on which the upper face of the second region is located so that an effective length between the selection transistor and the memory cell transistor may be sufficiently ensured. Thus, a disturbance phenomenon where an electron-hole-pair infiltrate into the memory cell transistor caused by a high integration degree of the flash memory device may be prevented. Further, the memory cell transistor having the Fin-FET structure may prevent a gate induced drain leakage (GIDL) from being increased.

In view of the description provided above, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

What is claimed is:

1. A flash memory device comprising:
a substrate having a first region and a second region, the first region having an upper surface located within a first plane and the second region having an upper surface located within a second plane different from the first plane;
a memory cell transistor formed on the first region, the memory cell transistor including a Fin-FET structure; and
a selection transistor formed on the second region.

2. The flash memory device of claim 1, wherein the first plane is higher than the second plane.

3. The flash memory device of claim 1, wherein the first plane is lower than the second plane.

4. The flash memory device of claim 1, wherein the selection transistor includes a Fin-FET structure and wherein the selection transistor and the memory cell transistor comprise silicon fins with upper surfaces that are substantially coplanar.

5. The flash memory device of claim 1, wherein the selection transistor includes a Fin-FET structure and wherein the selection transistor and the memory cell transistor comprise silicon fins, wherein an upper surface of the silicon fin of the selection transistor is lower than an upper surface of the silicon fin of the memory cell transistor.

6. The flash memory device of claim 1, wherein the selection transistor includes a Fin-FET structure and wherein the selection transistor and the memory cell transistor comprise silicon fins, wherein an upper surface of the silicon fin of the selection transistor is higher than an upper surface of the silicon fin of the memory cell transistor.

7. The flash memory device of claim 1, wherein the selection transistor has a substantially planar structure.

8. The flash memory device of claim 1, further comprising a plurality of selection transistors and a plurality of memory cell transistors, the plurality of selection transistors comprising:
a ground selection transistor adjacent to a first one of the plurality of memory cell transistors; and
a string selection transistor adjacent to a last one of the plurality of memory cell transistors.

9. The flash memory device of claim 1, wherein upper surfaces of the selection transistor and the memory cell transistor are not substantially coplanar.

10. A flash memory device comprising:
a substrate having a first region, a second region and a recess formed at an interface between the first region and the second region;
a memory cell transistor formed on the first region, the memory cell transistor including a Fin-FET structure; and
a selection transistor formed on the second region, the selection transistor including a Fin-FET structure.

11. A method of manufacturing a flash memory device, comprising:
preparing a substrate having a first region and a second region, the first region having an upper surface located within a first plane and the second region having an upper surface located within a second plane different from the first plane;
forming a memory cell transistor on the first region, the memory cell transistor including a Fin-FET structure; and
forming a selection transistor on the second region.

12. The method of claim 11, wherein the first plane is higher than the second plane.

13. The method of claim 12, wherein preparing the substrate includes performing a silicon epitaxial growth process on the first region.

14. The method of claim 12, wherein preparing the substrate includes etching the second region.

15. The method of claim 11, wherein the first plane is lower than the second plane.

16. The method of claim 15, wherein preparing the substrate includes performing a silicon epitaxial growth process on the second region.

17. The method of claim 15, wherein preparing the substrate includes etching the first region.

18. The method of claim 11, wherein upper surfaces of the selection transistor and the memory cell transistor are not substantially coplanar.

19. A method of manufacturing a flash memory device, comprising:
preparing a substrate having a first region, a second region and a recess formed at an interface between the first region and the second region;
forming a memory cell transistor on the first region, the memory cell transistor including a Fin-FET structure; and
forming a selection transistor on the second region, the selection transistor including a Fin-FET structure.
